(19) United States
(12) Patent Application Publication
(10) Pub. No.: US 2006/0063338 A1
(43) Pub. Date: Mar. 23, 2006

(54) Shallow trench isolation depth extension using oxygen implantation

(75) Inventors: Santosh S. Menon, Troutdale, OR (US); Hemanshu D. Bhatt, Vancouver, WA (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 10/946,030

(22) Filed: Sep. 20, 2004

(51) Int. Cl. H01L 21/336

(52) U.S. Cl. 438/296

(57) ABSTRACT

The present invention is directed to structures and fabrication methods used to construct an improved shallow trench isolation structure are disclosed. The method involves providing a semiconductor substrate having a shallow isolation trench. The trench is implanted with oxygen to form an implanted region at the bottom of the trench. The trench is filled with dielectric materials. The substrate is planarized and then annealed to complete formation of the isolation structure. A structure having an improved isolation structure is also disclosed. The structure comprises a substrate configured to include a shallow trench that is filled with dielectric material. An insulating extension is formed by oxygen implantation of the regions underlying the shallow trench.

### FIELD OF THE INVENTION

The invention described herein relates generally to semiconductor devices and processing. In particular, the present invention relates to methods, materials, and structures used in forming shallow isolation trenches having improved electrical isolation properties. More particularly, the invention relates to methods, materials, and structures for forming isolation trenches having insulating extensions that extend the depth of the overall insulation structure to enhance its electrical isolation properties.

### BACKGROUND OF THE INVENTION

Implementing electronic circuits involves connecting isolated devices through specific electronic paths. In integrated circuit fabrication it is generally necessary to isolate adjacent devices from one another. They are subsequently interconnected to create the desired circuit configuration. In the continuing trend toward higher device densities, parasitic inter-device current becomes problematic. Accordingly much attention is paid to isolation technologies.

A variety of successful isolation technologies have been developed to address the requirements of different integrated circuit types such as NMOS, CMOS and bipolar. In general, the various isolation technologies exhibit different attributes with respect to such characteristics as minimum isolation spacing, surface planarity, process complexity and defect density generated during isolation processing. Moreover, it is common to trade off some of these characteristics when developing an isolation process for a particular integrated circuit application.

For example, in metal-oxide-semiconductor (MOS) technology it is necessary to provide an isolation structure that prevents parasitic channel formation between adjacent devices, such devices being primarily NMOS or PMOS transistors or CMOS circuits. One widely used isolation technology for MOS circuits has been that of LOCOS isolation, an acronym for LOCal Oxidation of Silicon. LOCOS isolation essentially involves the growth of a recessed or semi-recessed oxide in unmasked non-active or field regions of the silicon substrate. This so-called field oxide is generally grown thick enough to lower any parasitic capacitance occurring over these regions, but not so thick as to cause step coverage problems. The great success of LOCOS isolation technology is to a large extent attributed to its inherent simplicity in MOS process integration, cost effectiveness and adaptability.

In spite of its success, several limitations of LOCOS technology have driven the development of alternative isolation structures. A well-known limitation in LOCOS isolation is that of oxide undergrowth at the edge of the mask which defines the active regions of the substrate. This so-called bird's beak (as it appears) poses a limitation to device density, since that portion of the oxide adversely influences device performance while not significantly contributing to device isolation. Another problem associated with the LOCOS process is the resulting circuit planarity or lack thereof. For submicron devices, planarity becomes an important issue, often posing problems with subsequent layer conformity and photolithography.

Trench isolation technology was developed in part to overcome the aforementioned limitations of LOCOS isolation for submicron devices. Shallow trench structures are prepared in a substrate surface and then prepared for filling with dielectric materials. These trenches are then filled. These refilled trench structures essentially comprise a recess formed in the silicon substrate which is refilled with an dielectric material. For example, such structures are fabricated by first forming micron-sized or submicron-sized trenches in the silicon substrate, usually by a dry anisotropic etching process. The resulting trenches typically display a steep sidewall profile as compared to LOCOS oxidation. The trenches are subsequently refilled with a dielectric such as chemical vapor deposited (CVD) silicon dioxide (SiO₂). They are then planarized by an etchback process so that the dielectric remains only in the trench, its top surface level with that of the silicon substrate. Other surface planarization techniques can be used. Active regions wherein devices are fabricated are those that lie between the trenches. The resulting trench structure functions as a device isolator having excellent planarity and a reasonable aspect ratio. Refilled trench isolation can take a variety of forms depending upon the specific application. Shallow Trench Isolation (STI) is used primarily for isolating devices of the same type and is often considered an alternative to LOCOS isolation. Shallow trench isolation has the advantages of eliminating the birds beak of LOCOS and providing a high degree of surface planarity. However, as circuit densities increase, the need for increased amounts of active circuit area to form them on also increases. This means it is desirable to make STI features narrower to free up more active circuit area. However, one difficulty with existing methods of STI is that at high aspect ratios (the ratio of trench depth D to trench width W) such trenches are difficult to fabricate and fill. This is especially the case with trenches less than 4000 Å wide and greater than about 3000 Å deep. Filling of such high aspect ratio trenches is commonly achieved using PECVD (Plasma Enhanced Chemical Vapor Deposition) techniques to deposit insulative materials such as SiO₂. However, when narrow, high aspect ratio trenches (less than 4000 Å wide with aspect ratios of greater than about 0.80) are filled, non-uniform filling can occur. Such non-uniformities can leave “keyhole” defects in the filler material. This phenomenon results from a phenomenon known in the industry as “breadloafing”. In short, material deposited near the top of the trench blocks material from reaching the bottom of the trench leaving voids (the keyholes). Subsequently, during use, conductive materials can migrate into the voids forming conduction paths through the isolation causing drastic increases in leakage currents between two adjacent circuit devices. This stands as a significant barrier to the construction of narrow but deep isolation structures. Moreover, using conventional approaches, etch stress begin to have a significant effect on final trench structure. For example, dislocations resulting from etch stress on the crystalline structure of the substrate can cause line defects. Such defects become increasingly common at etch depths of greater than about 3000 Å. Moreover, at etch depths of 4000 Å and greater, defect incidence renders such etching all but impossible. Additionally, such deep etching commonly results in corner rounding which eats up valuable active surface area. Thus, several different limitations of conventional techniques present obstacles to the formation of narrow deep isolation structures.

As the minimum feature size achievable in semiconductor manufacturing decreases, the capacitive coupling and current leakage between adjacent devices becomes a significant impediment to achieving higher performance. This is especially true for analog RF devices formed on the substrate. To counteract such increasing problems, designers and engineers have been looking for ways to reduce the capacitive coupling and leakage currents. One approach would be to devise methods and structures of forming deeper and narrower isolation trench structures.

For the reasons stated above, as well as other reasons apparent to those skilled in the art, there is a need in the art for alternative and improved isolation structures and methods of their construction and use in integrated circuits.

### SUMMARY OF THE INVENTION

In accordance with the principles of the present invention, a method and structure for an improved shallow trench isolation structure are disclosed. One embodiment of the present invention is directed to a semiconductor substrate. The substrate is configured to include a plurality of shallow trenches wherein the trenches define a plurality of active areas. The substrate further include semiconductor electrical isolation structures. The structures comprise filler of electrically insulative material formed in the trenches and insulating extensions underlying at least some of the shallow trenches. These extensions are comprised of a substantially electrically insulative material that extends a distance into the substrate underneath said at least some of the shallow trenches.

A method embodiment for forming electrical isolation structures is also disclosed. The method involves providing a semiconductor substrate having a plurality of shallow isolation trenches that define active circuit areas and have a pattern mask formed thereon wherein openings in the mask expose the substrate in the trenches. The process further includes implanting oxygen into the substrate at the bottoms of the trenches and depositing a filler of electrically insulative material into the trenches. The substrate is planarized and then annealed to complete formation of the isolation structures.

These and other features and advantages of the present invention are described below with reference to the drawings.

### BRIEF DESCRIPTION OF THE DRAWINGS

The following detailed description will be more readily understood in conjunction with the accompanying drawings, in which:

FIG. 1 is a simplified cross-section view schematically depicting a semiconductor wafer having a patterned mask in place on the wafer in accordance with the principles of the invention.

FIG. 2 is a simplified cross-section view schematically depicting the semiconductor wafer of FIG. 1 after etching to form shallow isolation trenches in accordance with the principles of the invention.

FIG. 3 is a simplified cross-section view schematically depicting the semiconductor wafer of FIG. 2 showing oxygen implantation of the shallow isolation trenches in accordance with the principles of the invention.

FIG. 4 is a simplified cross-section view schematically depicting the semiconductor wafer of FIG. 3 after deposition to fill the shallow isolation trenches in accordance with the principles of the invention.

FIG. 5 is a simplified cross-section view schematically depicting the semiconductor wafer of FIG. 4 after planarization of the surface in accordance with the principles of the invention.

FIGS. 6 and 7 are simplified cross-section views schematically depicting the semiconductor wafer of FIG. 5 after annealing of the substrate to complete the formation of the insulating extensions in accordance with the principles of the invention.

FIG. 8A is a simplified cross-section view schematically depicting the SOI semiconductor wafer after the formation of shallow trenches and prior to oxygen implantation of the surface in accordance with the principles of the invention.

FIG. 8B is a simplified cross-section view schematically depicting the SOI semiconductor wafer of FIG. 8A after implantation, planarization, and annealing in accordance with the principles of the invention.

It is to be understood that, in the drawings, like reference numerals designate like structural elements. Also, it is understood that the depictions in the Figures are not necessarily to scale.

### DETAILED DESCRIPTION

The present invention has been particularly shown and described with respect to certain embodiments and specific features thereof. The embodiments set forth hereinbelow are to be taken as illustrative rather than limiting. It should be readily apparent to those of ordinary skill in the art that various changes and modifications in form and detail may be made without departing from the spirit and scope of the invention.

In the following detailed description, various materials and method embodiments for constructing STI structures having isolation extensions will be disclosed. In particular, silicon dioxide isolation structures and the methods of their construction will be detailed.

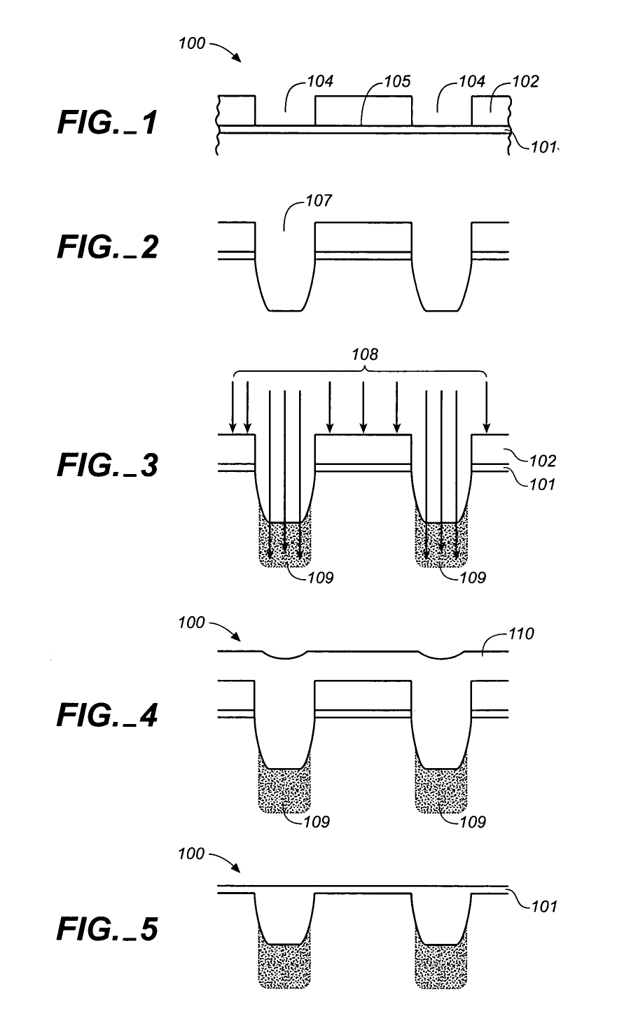

As depicted in FIG. 1, the embodiments begin by first providing a suitable substrate 100. As used herein, substrate refers to a semiconductor structure. Such structures can include, for example, a silicon wafer. Such wafer can be doped if required. The depicted wafer includes a pad silicon oxide layer and a SiN etch stop layer 101 formed on the top of the substrate. In the depicted embodiment, the etch stop 101 is silicon nitride. This nitride layer can be deposited on a silicon substrate 100, for example, through the LPCVD process. Those of ordinary skill in the art will appreciate that the etch stop 101 can be formed of many other materials.

A patterned mask layer 102 is formed on the etch stop 101. The patterned mask can be formed using any of a number of fabrication techniques known to those having ordinary skill in the art. The mask can be either a hard mask or a soft mask as desired. In one embodiment, the patterned mask layer 102 is formed of a photoimageable material (e.g., a photoresist material) and patterned using a conventional photolithographic process. In the depicted embodiment, the patterned mask layer 102 is formed including openings 104 that expose regions of the substrate that define shallow isolation trench regions of the substrate surface. Additionally, the patterned mask layer 102 covers regions of the substrate that will later become active device regions 105.

The substrate 100 of FIG. 1 is etched to remove material in the exposed regions to form shallow isolation trenches 107. These trenches 107 are depicted in FIG. 2. Typically, this etching is achieved using an anisotropic etch process. Dry etch processes such as reactive ion etching (RIE) and plasma etch can be used. It should be pointed out that up to this point the process is fairly conventional and many such processes for creating these shallow trenches can be employed. In accordance with embodiments of the invention the trenches can of any depth, but in some embodiment trenches of between about 1000 Å to about 4500 Å can be fabricated. Trenches having significantly greater depths become increasingly difficult to form. However, most commonly, embodiments of the invention are constructed having a depth of between about 3000 Å to about 4000 Å deep. Additionally, in the depicted embodiment, the trench is between about 2000 Å to about 4000 Å wide.

After this basic substrate 100 is configured, it is suitable for further processing in accordance with the principles of the invention. The substrate 100 is then placed in a processing chamber of an ion implantation machine. Examples of satisfactory implantation machines include, but are not limited to, a Paradigm or HE3 implanter (manufactured by Axcelis Technologies, Inc. of Beverly, Mass.) or VIISta300HP implanter (manufactured by Varian Semiconductor Equipment Associates, Inc. of Glouster, Mass.). The implanter is used to implant oxygen 108 into a portion of the substrate. The mask 102 and etch stop layer 101 protect the active regions of the substrate from such implantation. The implanted region 109 lies with the openings of the mask 102. A substantial portion of the oxygen implantation occurs at the bottom of the trenches. Additionally, in some embodiments (where the slope of the trench wall is significant) the sloped portions of the trench wall can also be oxygen implanted. The oxygen is implanted to create an implanted region 109 that extends a distance below the bottom of the trench. The deeper the implantation the better the isolation. Satisfactory embodiments can form an implanted region 109 that extends about 500 Å to about 2500 Å into the underlying substrate. In some embodiments the implanted region 109 extends between about 1500 Å to about 2000 Å below the bottom of the trench. An implantation power is used that will effectively achieve the desired implantation depth into the substrate material (e.g., silicon). In some embodiments an implantation power of in the range of about 50 keV to about 200 keV can be employed. As is known to those having ordinary skill in the art, this power can be varied in accordance with the requirements of the implantation apparatus and the needs of the user. Additionally, the oxygen implantation dose is adjusted as needed. Typically, a relatively high dose is used. In one embodiment, the implantation dose is adjusted so that two oxygen ions are implanted for each silicon atom in the implanted region 109. This figure can be calculated or determined empirically. In one embodiment, a dose range of 1×10⁺¹² to about 5×10⁺¹⁵ oxygen atoms per cm² can be used. An exposure time in the range of about 1-3 minutes is typically suitable. In one specific embodiment, a dose of 10⁺¹³ oxygen atoms per cm² can be used for an exposure time in the range of about 1 minute. The idea being that the implanted region 109 will be reacted to form a layer of silicon dioxide material, which is an excellent electrical insulator. Thus, providing a deeper isolation trench structure which reduces leakage currents between devices formed on the active areas and separated by the isolation structures.

As depicted in FIG. 4, an insulating layer 110, comprised of an electrically insulating material, is deposited on the substrate surface. Such dielectric material is commonly silicon dioxide. Such silicon dioxide layers can be formed using HDPCVD (high density plasma chemical vapor deposition) techniques or other plasma assisted techniques known to those having ordinary skill in the art. Additionally, other deposition and silicon dioxide layer formation techniques can be used. Additionally, beyond silicon dioxide, combinations of silicon dioxide and other doped dielectrics (e.g., BPSG, PSG) can be used. Additionally, low-K dielectric materials or other electrically isolating materials are also used. Examples include spin-on and CVD polymeric materials based on silicon or carbon, or based on combinations of silicon and carbon. Particular low-K materials include, but are not limited to: organic thermoplastic and thermosetting polymers such as polyimides, polyarylethers, benzocyclobutenes, polyphenylquino-xalines, polyquinolines; inorganic and spin-on glass materials such as silsesquioxanes, silicates, and siloxanes; and, mixtures, or blends, of organic polymers and spin-on glasses. Further, examples of CVD low-K materials include polymers of parylene and napthalene, copolymers of parylene with polysiloxanes or teflon, and polymers of polysiloxane. Additionally, foamed polymeric materials and cured aerogels may be employed. Such materials include but are not limited to methylsilsesquioxanes and polynorbornenes and additionally polyimides (e.g., Type I and Type III polyimides). Further details of such materials can be found, for example, in U.S. Pat. Nos. 6,413,827 and 6,781,192 which are hereby incorporated by reference. This list of materials is not intended to be exhaustive but rather illustrative.

In accordance with one embodiment of the present invention, and with respect to FIG. 5, the excess portions of the insulating layer 110 are removed from the surface. Also, the mask layer 102 is removed from the substrate. This can be achieved using a number of methods known to those having ordinary skill in the art. For example, the layers can be removed using etch techniques. Or in another embodiment, the excess material is removed using chemical mechanical polishing (CMP). Such CMP or etching continues until the mask is removed and generally until the etch stop 101 is reached. Typically, the remaining etch stop material is also removed. For example, if the etch stop 101 is formed of silicon nitride, phosphoric acid or some other suitable material can be used to remove the etch stop 101 down to the underlying substrate.

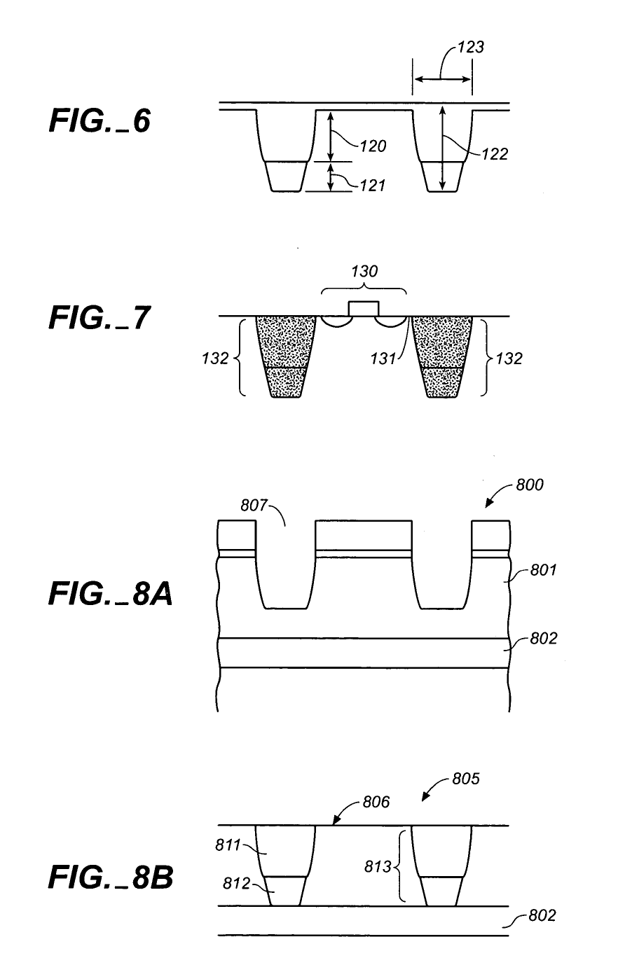

After the mask and etch stop are removed, the substrate 100 is annealed. Such annealing is conducted at between about 1200° C. to about 1400° C. (for example, about 1350° C.) to react the implanted oxygen with the silicon of the substrate. The reaction forms silicon dioxide and forms electrically insulating trench extensions in the implanted region 109. In this way, an isolation structure can be formed that includes the trench and the underlying trench extension. Thus, a deeper isolation structure can be formed having a narrow width. Aspect ratios of greater than one can be achieved in this way. For example, referring to FIG. 6 if a trench depth 120 of about 4000 Å is coupled with an extension having an extension depth 121 of another 2000 Å, a total depth 122 for the isolation structure of about 6000 Å can be achieved. Moreover, this depth can be achieved while having a width 123 of about 3000-4000 Å. Thus, aspect ratios in the approximate range of 1.5-3.0 can be achieved with this technology.

Reference to FIG. 7 shows an integrated circuit device 130 formed on an active area 131 of the surface defined by two isolation structures 132 constructed in accordance with the principles of the invention.

FIG. 8 depicts a substrate similar to that depicted in FIG. 2 with one significant difference. The substrate 800 is a silicon-on-insulator (SOI) substrate. A top silicon layer 801 is formed on an insulator 802 (e.g., sapphire or other highly insulative material). Here, the shallow trenches 807 are etched into the silicon. As with, for example, FIG. 3, the substrate is implanted with oxygen ions to form an implanted region. In this embodiment, the implanted region is formed to a depth that permits contact with the underlying insulation 802. After the trench is filled and the surface planarized the substrate is annealed to complete the formation of the substrate. This, substrate can be used to have further semiconductor structures formed thereon. FIG. 8B illustrates one embodiment of such a structure. The filled trench 811 has an insulating extension 812 that extends the trench until it reaches the insulation layer 802. The complete isolation structure 813 extends from the surface to the insulation layer 802 thereby providing high quality electrical insulation to a great depth (indeed, here until the insulator layer 802 is reached). As with the embodiment depicted on FIG. 6, the completed isolation structure 805 is suitable for having further circuit structures formed thereon. For example, a transistor element can be formed on active area 806.

The present invention has been particularly shown and described with respect to certain embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Further, reference in the claims to an element in the singular is not intended to mean “one and only one” unless explicitly stated, but rather, “one or more”.

What is claimed is:

1. A semiconductor circuit structure, comprising:
a semiconductor substrate having a plurality of shallow trenches formed thereon, the trenches defining a plurality of active areas;
semiconductor electrical isolation structure including:
a filler of electrically insulative material formed in the trenches; and
insulating extensions underlying at least some of the shallow trenches, the extensions extending a distance into the substrate underneath said shallow trenches.

2. The semiconductor circuit structure of claim 1 wherein the substrate comprises a silicon substrate and wherein the insulator extensions include silicon dioxide material formed by implantation of oxygen into the silicon substrate underlying the shallow trenches.

3. The semiconductor circuit structure of claim 2 wherein the filler of electrically insulative material comprises a silicon dioxide material.

4. The semiconductor circuit structure of claim 2 wherein the filler of electrically insulative material comprises a filler material selected from the group consisting of a foamed polymeric material and a cured aerogel.

5. The semiconductor circuit structure of claim 4 wherein the foamed polymeric material comprises a polymeric material selected from the group consisting of methylsilsesquioxane, polyimides and polynorbornenes.

6. The semiconductor circuit structure of claim 4 wherein the foamed polymeric material comprises a polymeric material selected from the group consisting of Type I and Type III polyimides.

7. The semiconductor circuit structure of claim 2 wherein the substrate comprises a silicon-on-insulator (SOI) substrate having an underlying insulator layer and wherein the insulator extensions extend into said insulator layer.

8. The semiconductor circuit structure of claim 2 wherein the active areas have semiconductor integrated circuit elements formed thereon and
wherein a combination of shallow trench and insulating extension form the semiconductor electrical isolation structure which extends into the substrate to a depth sufficient to substantially inhibit leakage current between two integrated circuit elements separated by the semiconductor electrical isolation structure.

9. The semiconductor circuit structure of claim 8 wherein the shallow trench has a depth of in the range of about 1000 Å to about 4500 Å and wherein insulator extension extends into the substrate a further distance of in the range of about 500 Å to about 2500 Å.

10. The semiconductor circuit structure of claim 9 wherein the shallow trench has a depth of in the range of about 3000 Å to about 4000 Å and wherein insulator extension extends into the substrate a further distance of in the range of about 1500 Å to about 2000 Å.

11. The semiconductor circuit structure of claim 2 wherein the semiconductor electrical isolation structure has a width of in the range of about 2000 Å to about 4000 Å and wherein the aspect ratio of depth D to width W for the semiconductor electrical isolation structure is greater than about 1.

12. The semiconductor circuit structure of claim 2 wherein the semiconductor electrical isolation structure has a width of in the range of about 3000 Å to about 4000 Å.

13. The semiconductor circuit structure of claim 11 wherein the semiconductor electrical isolation structure is in the range of about 3000 Å to about 4000 Å wide and in the range of about 5000 Å to about 6000 Å deep.

14. A method of forming a shallow isolation trench with insulator extensions on a semiconductor substrate, the method comprising:
providing a semiconductor substrate having a plurality of shallow isolation trenches, wherein the substrate further includes a pattern mask layer that covers at least some active portions of the substrate and has openings that expose portions of the substrate wherein at least some of the exposed portions of substrate are within the shallow isolation trenches;
implanting oxygen into the substrate within shallow isolation trenches;
depositing a filler of electrically insulative material into the isolation trenches;
removing the mask from the substrate; and
annealing the substrate.

15. The method of claim 14 wherein implanting oxygen into the substrate within shallow isolation trenches comprises implanting oxygen into the substrate at the bottom of the shallow isolation trenches.

16. The method of claim 14 wherein said shallow isolation trenches have a depth of in the range of about 3,000 Å to about 4,000 Å; and
wherein implanting oxygen into the substrate at the bottoms of the trenches comprises implanting the oxygen to a depth of in the range of 1,500 Å to about 2,000 Å into the substrate.

17. The method of claim 16, wherein said shallow isolation trenches are less than about 4,000 Å wide.

18. The method of claim 16 wherein annealing the substrate comprises annealing the substrate at a temperature in the range of about 1300° C. to about 1400° C.

19. The method of claim 14 wherein implanting oxygen into the substrate at the bottoms of the trenches comprises implanting the oxygen at a power of in the range of about 50 keV to about 200 keV.

20. The method of claim 14 wherein providing a semiconductor substrate includes providing the with a pattern mask layer that comprises photoresist material.

21. The method of claim 14 wherein removing the mask includes chemical mechanical polishing of the surface of the substrate.

22. The method of claim 14 wherein
providing the substrate includes providing a substrate having an etch stop layer that underlies the pattern mask layer; and
wherein removing the mask includes chemical mechanical polishing the surface of the substrate until the mask is removed and the etch stop is exposed and then removing the etch stop.

23. A method of forming a shallow isolation trench with insulator extensions on a semiconductor substrate, the method comprising:
providing a semiconductor substrate having a top surface with an etch stop material formed thereon;
forming a pattern mask on the etch stop material;
anisotropically etching away surface materials, through openings in the mask to form shallow trenches in the substrate surface;
implanting oxygen into the substrate in the shallow trenches;
depositing a filler of electrically insulative material into the shallow trenches;
polishing the surface until the mask is removed and the etch stop material is reached;
removing the etch stop material; and
annealing the substrate.
